(19) United States
(12) Patent Application Publication
(10) Pub. No.: US 2026/0271316 A1
(43) Pub. Date: Sep. 10, 2026

(54) SEMICONDUCTOR DEVICE AND METHOD FOR MANUFACTURING THE SAME

(71) Applicants: KABUSHIKI KAISHA TOSHIBA, Kawasaki-shi (JP); Toshiba Electronic Devices & Storage Corporation, Kawasaki-shi (JP)

(72) Inventors: Ryuichi TAMAI, Nonoichi Ishikawa (JP); Kazuki MINAMIKAWA, Nomi Ishikawa (JP)

(73) Assignees: KABUSHIKI KAISHA TOSHIBA, Kawasaki-shi (JP); Toshiba Electronic Devices & Storage Corporation, Kawasaki-shi (JP)

(21) Appl. No.: 19/358,701

(22) Filed: Oct. 15, 2025

(30) Foreign Application Priority Data
Mar. 7, 2025 (JP) 2025-036592

(51) Int. Cl. H10D 12/00; H10D 8/00; H10D 12/01; H10D 30/63; H10D 62/10; H10D 64/00; H10D 64/27

(52) U.S. Cl. CPC H10D 12/481; H10D 12/038; H10D 12/415; H10D 62/102; H10D 62/126; H10D 64/112; H10D 64/117; H10D 8/411; H10D 30/63; H10D 62/103; H10D 64/513

(57) ABSTRACT

According to one embodiment, a semiconductor device includes first to third electrodes, a semiconductor layer, and, a first layer. The semiconductor layer includes first and second portions. The second portion is provided around the first portion along a first plane. The third electrode is provided on the second portion via an insulating layer and located around the second electrode along the first plane. A length of an upper part of the third electrode in a first direction is shorter than a length of a lower part of the third electrode in the first direction. The first direction is from the first portion toward the second portion. The first layer is provided on the third electrode and electrically connected to the third electrode. A length of the first layer in the first direction is greater than the length of the upper part.

### CROSS-REFERENCE TO RELATED APPLICATIONS

This application is based upon and claims the benefit of priority from Japanese Patent Application No.2025-036592, filed on Mar. 7, 2025; the entire contents of which are incorporated herein by reference.

### FIELD

Embodiments described herein relate generally to a semiconductor device and a method for manufacturing the same.

### BACKGROUND

Semiconductor devices including Insulated Gate Bipolar Transistors (IGBT) are used in applications such as power conversion. It is desirable that the withstand voltage of the semiconductor devices is stable.

### BRIEF DESCRIPTION OF THE DRAWINGS

FIG. 1 is a plan view illustrating a semiconductor device according to a first embodiment;

FIG. 2 is a plan view illustrating the semiconductor device according to the first embodiment.

FIG. 3 is the III-III cross-sectional view of FIGS. 1 and 2;

FIG. 4 is the IV-IV cross-sectional view of FIGS. 1 and 2;

FIG. 5 is the V-V cross-sectional view of FIGS. 1 and 2;

FIGS. 6A to 6C are cross-sectional views illustrating a manufacturing method according to the first embodiment;

FIGS. 7A to 7C are cross-sectional views illustrating the manufacturing method according to the first embodiment;

FIGS. 8A to 8C are cross-sectional views illustrating the manufacturing method according to the first embodiment;

FIGS. 9A to 9C are cross-sectional views illustrating the manufacturing method according to the first embodiment;

FIGS. 10A and 10B are cross-sectional views illustrating the manufacturing method according to the first embodiment;

FIGS. 11A to 11C are cross-sectional views illustrating the manufacturing method according to the first embodiment;

FIGS. 12A to 12C are cross-sectional views illustrating the manufacturing method according to the first embodiment;

FIGS. 13A to 13C are cross-sectional views illustrating the manufacturing method according to the first embodiment;

FIG. 14 is a cross-sectional view illustrating a part of a semiconductor device according to a reference example;

FIGS. 15A to 15C are cross-sectional views illustrating a manufacturing method according to the reference example;

FIGS. 16A and 16B are cross-sectional views illustrating a part of a semiconductor device according to a modification of the first embodiment;

FIG. 17 is a cross-sectional view illustrating a part of a semiconductor device according to a second embodiment; and

FIG. 18 is a cross-sectional view illustrating a part of a semiconductor device according to a third embodiment.

### DETAILED DESCRIPTION

According to one embodiment, a semiconductor device includes a first electrode, a semiconductor layer, a second electrode, a third electrode, and a first layer. The semiconductor layer is provided on the first electrode. The semiconductor layer includes a first portion and a second portion. The second portion is provided around the first portion along a first plane. The first plane is perpendicular to a direction from the first electrode toward the semiconductor layer. The second electrode is provided on the first portion. The third electrode is provided on the second portion via an insulating layer. The third electrode is located around the second electrode along the first plane. A length of an upper part of the third electrode in a first direction is shorter than a length of a lower part of the third electrode in the first direction. The first direction is from the first portion toward the second portion. The first layer is provided on the third electrode and electrically connected to the third electrode. A length of the first layer in the first direction is greater than the length of the upper part.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. In the drawings and the specification of the application, components similar to those described thereinabove are marked with like reference numerals, and a detailed description is omitted as appropriate.

In the following descriptions and drawings, the notations n⁺, n⁻ and p⁺, p represent relative levels of impurity concentrations in conductivity types. That is, n⁺ indicates that the concentration of n-type dopants is relatively higher than that of n, and n⁻ indicates that the concentration of n-type dopants is relatively lower than that of n. Similarly, p⁺ indicates that the concentration of p-type dopants is relatively higher than that of p, and p⁻ indicates that the concentration of p-type dopants is relatively lower than that of p.

The embodiments described below may be implemented by reversing the p-type and the n-type of the semiconductor regions.

### First Embodiment

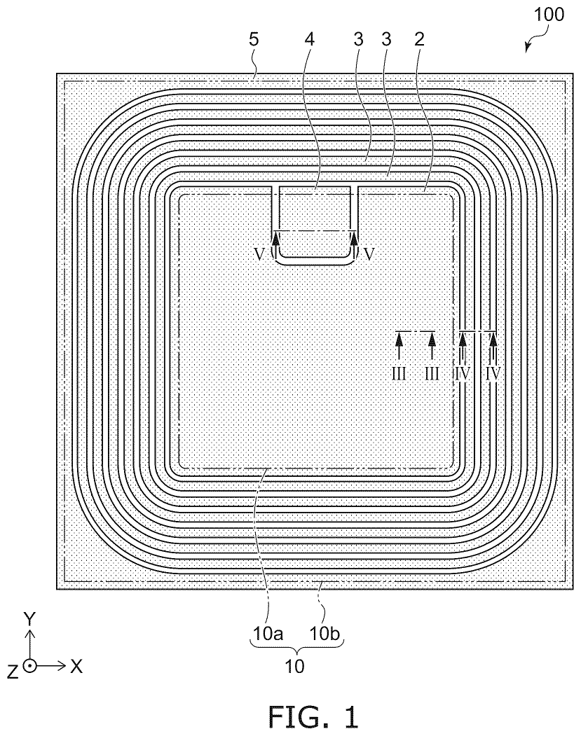

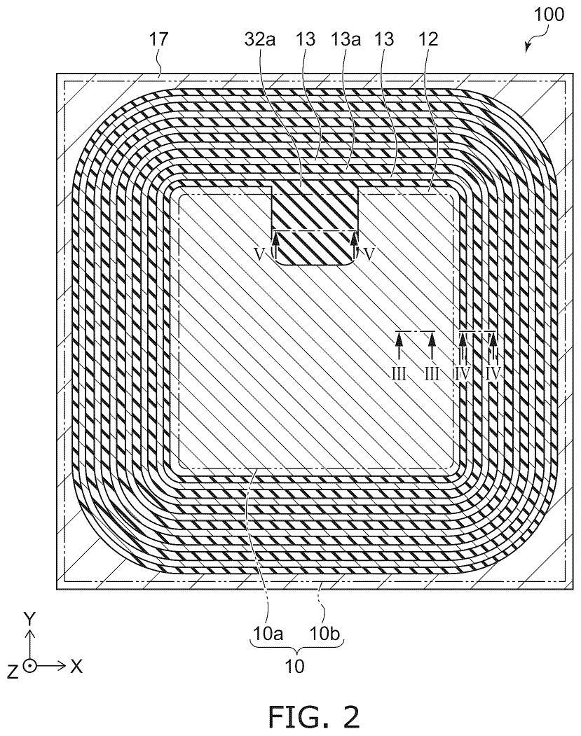

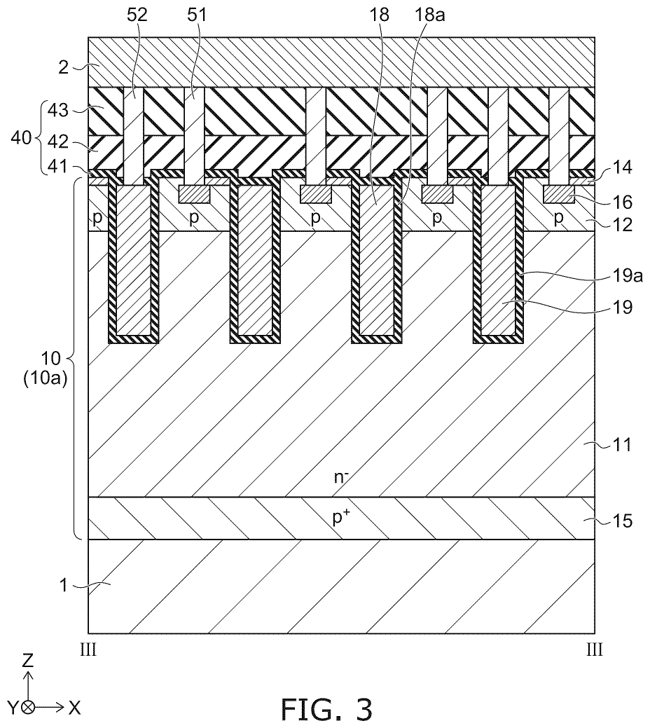

FIGS. 1 and 2 are plan views illustrating a semiconductor device according to a first embodiment. FIGS. 3 to 5 are, respectively, the III-III cross-sectional view, the IV-IV cross-sectional view, and the V-V cross-sectional view of FIGS. 1 and 2.

The semiconductor device 100 according to the first embodiment is an IGBT. As shown in FIGS. 1 to 5, the semiconductor device 100 includes a lower electrode 1 (first electrode), an upper electrode 2 (second electrode), a guard ring electrode 3 (GR electrode: third electrode), a gate pad 4, a peripheral electrode 5, a semiconductor layer 10, a first layer 21, a second layer 22, a first conductive layer 31, a second conductive layer 32, an insulating layer 40, an insulating layer 45, and contact plugs 51 to 54. In FIG. 1, the first layer 21, the second layer 22, and the insulating layer 45 are omitted. Also, in FIG. 2, the upper electrode 2, the guard ring electrode 3, the gate pad 4, the peripheral electrode 5, a part of the semiconductor layer 10, the first layer 21, the second layer 22, the first conductive layer 31, the second conductive layer 32, the insulating layer 40, the insulating layer 45, and the contact plugs 51 to 54 are omitted.

An XYZ orthogonal coordinate system is used in the description of the embodiments. A direction from the lower electrode 1 toward the semiconductor layer 10 is taken as a Z-direction (a first direction). Two mutually-orthogonal directions perpendicular to the Z-direction are taken as an X-direction (a second direction) and a Y-direction (a third direction). In the description, the direction from the lower electrode 1 toward the semiconductor layer 10 is referred to as “up/above”, and the opposite direction is referred to as “down/below”. These directions are based on the relative positional relationship between the lower electrode 1 and the semiconductor layer 10, and are independent of the direction of gravity.

As shown in FIG. 1, on the upper surface of the semiconductor device 100, an upper electrode 2, a guard ring electrode 3, a gate pad 4, and a peripheral electrode 5 are provided. The upper electrode 2 and the gate pad 4 are separated from each other and electrically isolated. The guard ring electrode 3 is provided around the upper electrode 2 and the gate pad 4 along the X-Y plane (a first plane), and is separated from the upper electrode 2 and the gate pad 4. The peripheral electrode 5 is provided around the GR electrode 3 along the X-Y plane, and is separated from the GR electrode 3.

As shown in FIGS. 1 and 2, the semiconductor layer 10 includes a first portion 10a and a second portion 10b. The first portion 10a includes the central part of the semiconductor device 100 in the X-Y plane. The second portion 10b is located around the first portion 10a along the X-Y plane. The first portion 10a is the cell part. The cell part is the region through which current mainly flows during the operation of the semiconductor device 100. The second portion 10b is the termination part. The termination part is the region in which, under voltage-withstand conditions of the semiconductor device 100, a depletion layer extends toward the periphery of the semiconductor device 100.

The upper electrode 2 and the gate pad 4 are provided on the first portion 10a. The guard ring electrode 3 and the peripheral electrode 5 are provided on the second portion 10b. Multiple guard ring electrodes 3 are provided in a first direction from the first portion 10a toward the second portion 10b. For example, in the X-Z cross-sectional view passing through the center of the first portion 10a in the X-Y plane, the first direction is parallel to the X-direction. In the Y-Z cross-sectional view passing through the center of the first portion 10a in the X-Y plane, the first direction is parallel to the Y-direction. In the example shown in FIGS. 1 and 2, the first direction corresponds to the direction from the center of the semiconductor device 100 in the X-Y plane toward the periphery of the semiconductor device 100. The multiple guard ring electrodes 3 are separated from each other in the first direction. The peripheral electrode 5 is provided around the multiple GR electrodes 3.

As shown in FIGS. 2 to 5, the semiconductor layer 10 includes an n⁻-type semiconductor region 11 (first semiconductor region), a p-type semiconductor region 12 (second semiconductor region), a p⁺-type guard ring region 13 (third semiconductor region), an n⁺-type semiconductor region 14 (fourth semiconductor region), a p⁺-type collector region 15 (fifth semiconductor region), a p⁺-type contact region 16, an n⁺-type stopper region 17, a gate electrode 18, and a field plate electrode 19. The n-type is an example of a first conductivity type. The p-type is an example of a second conductivity type.

As shown in FIGS. 3 to 5, the p⁺-type collector region 15 is provided in the first portion 10a and the second portion 10b, and is located in the lower part of the semiconductor layer 10. The p⁺-type collector region 15 is electrically connected to the lower electrode 1. The n⁻-type semiconductor region 11 is provided on the p⁺-type collector region 15.

As shown in FIG. 3, the p-type semiconductor region 12 is provided on the n⁻-type semiconductor region 11 and located in the first portion 10a. The n⁺-type semiconductor region 14 and the p⁺-type contact region 16 are provided on the p-type semiconductor region 12. For example, multiple p-type semiconductor regions 12, multiple n⁺-type semiconductor regions 14, and multiple p⁺-type contact regions 16 are provided in the X-direction. Each p-type semiconductor region 12, each n⁺-type semiconductor region 14, and each p⁺-type contact region 16 extend in the Y-direction.

The gate electrode 18 faces at least a part of the p-type semiconductor region 12 via a gate insulating layer 18a in the X-direction. The field plate electrode 19 faces at least a part of the p-type semiconductor region 12 via an insulating layer 19a in the X-direction. For example, multiple gate electrodes 18 and a single field plate electrode 19 are alternately arranged in the X-direction. Each gate electrode 18 and each field plate electrode 19 extend in the Y-direction. The p-type semiconductor regions 12 are respectively provided between adjacent gate electrodes 18 and between the gate electrode 18 and the field plate electrode 19.

The insulating layer 40 is provided on the semiconductor layer 10. For example, the insulating layer 40 includes insulating layers 41 to 43. The insulating layer 41 is in contact with the upper surface of the semiconductor layer 10. The insulating layer 42 is provided on the insulating layer 41. The insulating layer 43 is provided on the insulating layer 42.

The upper electrode 2 is located on the first portion 10a. Multiple contact plugs 51 and multiple contact plugs 52 are provided between the semiconductor layer 10 and the upper electrode 2. The contact plug 51 extends in the Z-direction through the insulating layer 40 and electrically connects the p-type semiconductor region 12, the n⁺-type semiconductor region 14, and the p⁺-type contact region 16 with the upper electrode 2. The contact plug 52 extends in the Z-direction through the insulating layer 40 and electrically connects the field plate electrode 19 with the upper electrode 2.

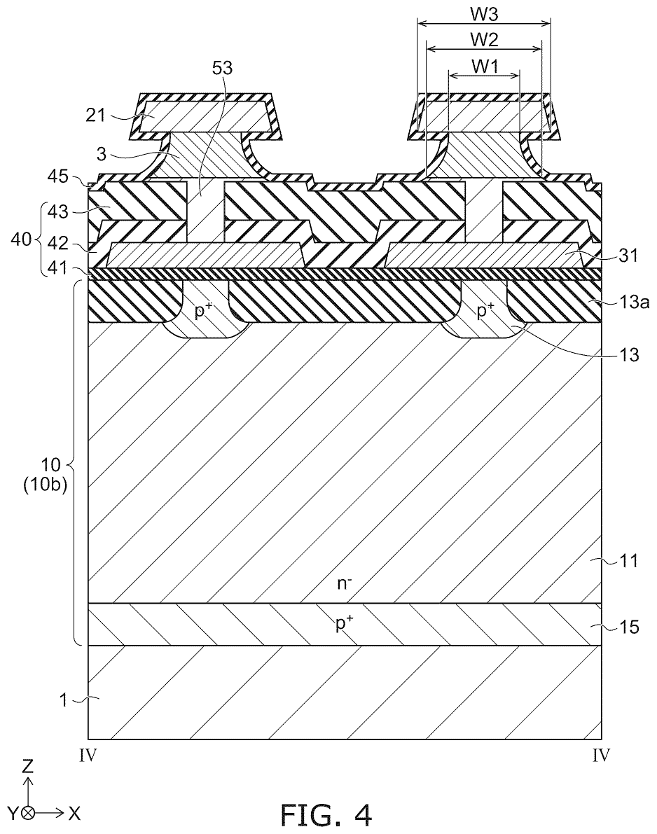

As shown in FIG. 4, the p⁺-type guard ring region 13 is provided on the n⁻-type semiconductor region 11 and is located in the second portion 10b. The p⁺-type guard ring region 13 is positioned around multiple p-type semiconductor regions 12 along the X-Y plane. Multiple p⁺-type guard ring regions 13 are provided in the first direction. In the cross-sectional view shown in FIG. 4, the first direction is parallel to the X-direction. The multiple p⁺-type guard ring regions 13 are separated from each other in the first direction.

Between adjacent p⁺-type guard ring regions 13 in the first direction, a part of the n⁻-type semiconductor region 11 may be provided, or, as shown in FIG. 4, an insulating portion 13a may be provided. As shown in FIG. 2, the n⁺-type stopper region 17 is provided around multiple p⁺-type guard ring regions 13 along the X-Y plane. The n⁺-type stopper region 17 is separated from the p⁺-type guard ring region 13. The n-type impurity concentration in the n⁺-type stopper region 17 is greater than the n-type impurity concentration in the n⁻-type semiconductor region 11.

As shown in FIG. 4, the GR electrode 3 is positioned above the p⁺-type guard ring region 13 via the insulating layer 41. In the illustrated example, the insulating layer 41 is provided on the p⁺-type guard ring region 13, and the first conductive layer 31 is provided on the insulating layer 41. The contact plug 53 is provided on the first conductive layer 31. The GR electrode 3 is located on the contact plug 53. The contact plug 53 extends in the Z-direction through the insulating layers 42 and 43, and electrically connects the first conductive layer 31 and the GR electrode 3.

The width W1 of the upper part of the GR electrode 3 is narrower than the width W2 of the lower part of the GR electrode 3. “Width” is the length in the first direction. In the cross-sectional view shown in FIG. 4, the width corresponds to the length in the X-direction. For example, the width of the GR electrode 3 gradually decreases toward the top.

The first layer 21 is provided on the GR electrode 3 and is electrically connected to the GR electrode 3. The width W3 of the first layer 21 is wider than the width W1 of the upper part of the GR electrode 3. The width W3 of the first layer 21 may be wider than the width W2 of the lower part of the GR electrode 3 as illustrated, or it may be narrower than the width W2. The first layer 21 is not in direct contact with the lower part of the GR electrode 3. The insulating layer 45 covers the upper surface of the insulating layer 40, the side surface of the GR electrode 3, and the surface of the first layer 21.

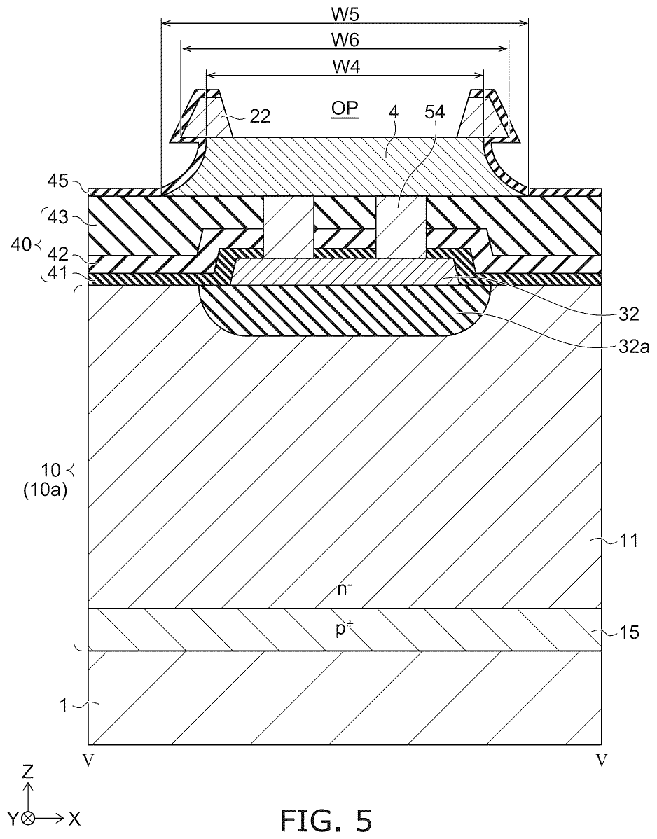

As shown in FIG. 5, in the first portion 10a, an insulating portion 32a is provided on a part of the n⁻-type semiconductor region 11. The second conductive layer 32 is provided on the insulating portion 32a, and the gate pad 4 is positioned on the second conductive layer 32. The contact plug 54 extends in the Z-direction through the insulating layers 42 and 43, electrically connecting the second conductive layer 32 and the gate pad 4.

The second layer 22 is provided on the gate pad 4 and is electrically connected to the gate pad 4. The width W4 of the upper part of the gate pad 4 is narrower than the width W5 of the lower part of the gate pad 4. For example, the width of the gate pad 4 gradually decreases toward the top. The width W6 of the second layer 22 is wider than the width W4 of the upper part of the gate pad 4. The width W6 of the second layer 22 may be narrower than the width W5 of the lower part of the gate pad 4 as illustrated, or it may be wider than the width W5.

The insulating layer 45 covers the side surface of the gate pad 4 and the surface of the second layer 22. The second layer 22 and the insulating layer 45 have an opening OP above the gate pad 4. A portion of the upper surface of the gate pad 4 is exposed to the outside through the opening OP.

An example of a material for each element will be described. The lower electrode 1, the upper electrode 2, the GR electrode 3, the gate pad 4, and the peripheral electrode 5 include aluminum. In addition to aluminum, the lower electrode 1, the upper electrode 2, the GR electrode 3, the gate pad 4, and the peripheral electrode 5 may include copper or silicon.

The semiconductor layer 10 includes silicon, silicon carbide, gallium nitride, or gallium arsenide as a semiconductor material. When silicon is used as the semiconductor material, arsenic, phosphorus, or antimony can be used as the n-type impurity. Boron can be used as the p-type impurity.

The gate electrode 18, the field plate electrode 19, the first conductive layer 31, and the second conductive layer 32 include a semiconductor material such as polysilicon. The gate electrode 18, the field plate electrode 19, the first conductive layer 31, and the second conductive layer 32 are doped with n-type impurities or p-type impurities to reduce electrical resistance.

The first layer 21 and the second layer 22 include one or more selected from the first group consisting of silicon, gold, tungsten, titanium, copper, and tin.

The electrical resistivity of the first layer 21 may be greater than the electrical resistivity of the GR electrode 3, the first conductive layer 31, etc.

As long as the first layer 21 has conductivity allowing charge to move between the first layer 21 and the GR electrode 3, the first layer 21 may be semi-insulating. The first layer 21 may include a compound of an element selected from the first group. As one example, the first layer 21 includes semi-insulating silicon nitride (SInSiN). The electrical resistivity of the first layer 21 is less than the electrical resistivity of an insulating layer composed of stoichiometric silicon nitride (Si₃N₄). As another example, the first layer 21 may include conductive tin oxide.

Similar to the first layer 21, the electrical resistivity of the second layer 22 may be greater than the electrical resistivity of the gate pad 4, the second conductive layer 32, etc. As long as the second layer 22 has conductivity allowing charge to move between the second layer 22 and the gate pad 4, the second layer 22 may be semi-insulating.

For example, the electrical resistivity of each of the first layer 21 and the second layer 22 is greater than 1.0×10⁸ Ω·cm and less than 1.0×10¹³ Ω·cm. The electrical resistivity of each of the first layer 21 and the second layer 22 may be less than 1.0×10¹² Ω·cm, and may even be less than 1.0×10¹¹ Ω·cm.

The insulating layers 41 to 43 include an insulating material such as silicon oxide, silicon nitride, or silicon oxynitride. For example, the insulating layers 41 to 43 include silicon oxide. The insulating layers 41 and 42 are substantially free of impurities. The insulating layer 43 includes one or more selected from p-type and n-type impurities. As one example, the insulating layer 41 is formed by thermal oxidation of the semiconductor layer 10. The insulating layer 42 is a Non doped Silicate Glass (NSG) film and is formed by chemical vapor deposition (CVD). The insulating layer 43 is a Boron Phosphorous doped Silicate Glass (BPSG) film and is formed by CVD. The insulating layer 45 includes an insulating material such as silicon nitride and functions as a passivation layer.

The contact plugs 51 to 54 include a metal material such as tungsten or titanium. For example, the contact plugs 51 to 54 include a titanium layer, a titanium nitride layer formed on the titanium layer, and a tungsten layer formed on the titanium nitride layer.

The operation of the semiconductor device 100 is described. In the semiconductor device 100, the lower electrode 1 functions as a collector electrode. The upper electrode 2 functions as an emitter electrode. When a positive voltage is applied to the lower electrode 1 relative to the upper electrode 2, a voltage exceeding the threshold is applied to the gate electrode 18. As a result, a channel (inversion layer) is formed in the p-type semiconductor region 12. Electrons flow through the channel from the n⁺-type semiconductor region 14 into the n⁻-type semiconductor region 11, and holes flow from the p⁺-type collector region 15 to the n⁻-type semiconductor region 11. The carrier density accumulated in the n⁻-type semiconductor region 11 increases, and conductivity modulation occurs. Consequently, the electrical resistance of the n⁻-type semiconductor region 11 is greatly reduced; and the semiconductor device 100 is turned on. Thereafter, when the voltage applied to the gate electrode 18 falls below the threshold, the channel in the p-type semiconductor region 12 disappears; and the semiconductor device 100 switches to an off-state.

When the semiconductor device 100 switches to an off-state, due to the potential difference between the lower electrode 1 and the upper electrode 2, a depletion layer expands from the p-n junction between the n⁻-type semiconductor region 11 and the p-type semiconductor region 12. In the second portion 10b, the depletion layer expands toward the periphery of the semiconductor device 100. When the p⁺-type guard ring region 13 and the GR electrode 3 are provided, the expansion of the depletion layer becomes stabilized. In addition, the n⁺-type stopper region 17 serves to suppress the expansion of the depletion layer at the periphery of the semiconductor device 100 and to prevent the depletion layer from reaching the periphery.

More specifically, the electric potential of the n⁺-type stopper region 17 and the peripheral electrode 5 are substantially the same as that of the lower electrode 1. Between the upper electrode 2 and the peripheral electrode 5, a potential gradient is formed along the first direction. The electric potential of each GR electrode 3 is determined according to its position in the first direction. The electric potential of the p⁺-type guard ring region 13 is determined according to the potential of the GR electrode 3. By so setting the potential of each p⁺-type guard ring region 13, the expansion of the depletion layer in the second portion 10b is stabilized. As a result, the withstand voltage of the semiconductor device 100 can be stabilized.

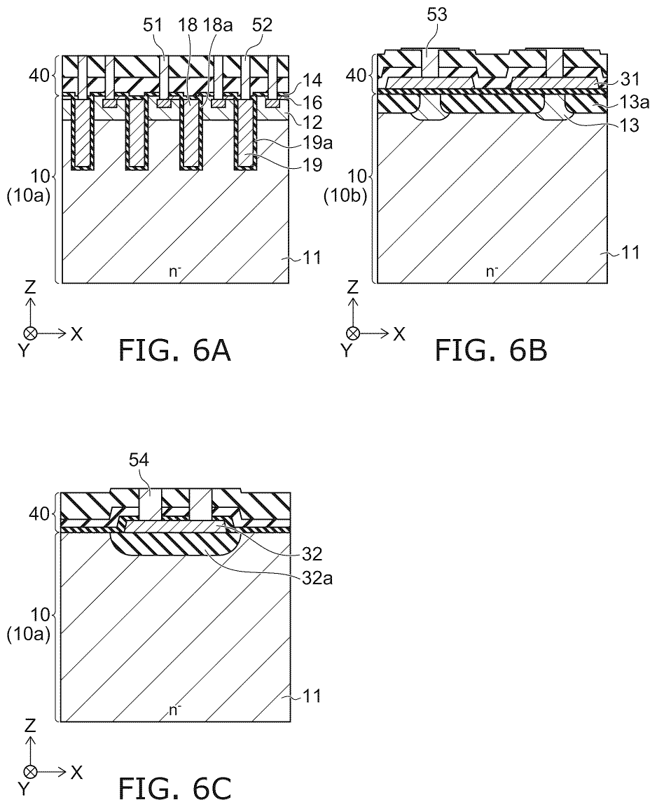

FIGS. 6A to 13C are cross-sectional views illustrating a manufacturing method according to the first embodiment.

FIGS. 6A, 7A, 8A, 9A, 11A, 12A, and 13A show manufacturing steps in the III-III cross-section of FIGS. 1 and 2. FIGS. 6B, 7B, 8B, 9B, 10B, 11B, 12B, and 13B show manufacturing steps in the IV-IV cross-section of FIGS. 1 and 2. FIGS. 6C, 7C, 8C, 9C, 11C, 12C, and 13C show manufacturing steps in the V-V cross-section of FIGS. 1 and 2.

First, a structure shown in FIGS. 6A to 6C is prepared using a conventional method. The structure includes the semiconductor layer 10, the first conductive layer 31, the second conductive layer 32, the insulating layer 40, and the contact plugs 51 to 54. The semiconductor layer 10 includes the n⁻-type semiconductor region 11, the p-type semiconductor region 12, the p⁺-type guard ring region 13, the n⁺-type semiconductor region 14, the p⁺-type contact region 16, the n⁺-type stopper region 17 (not shown), the gate electrode 18, and the field plate electrode 19.

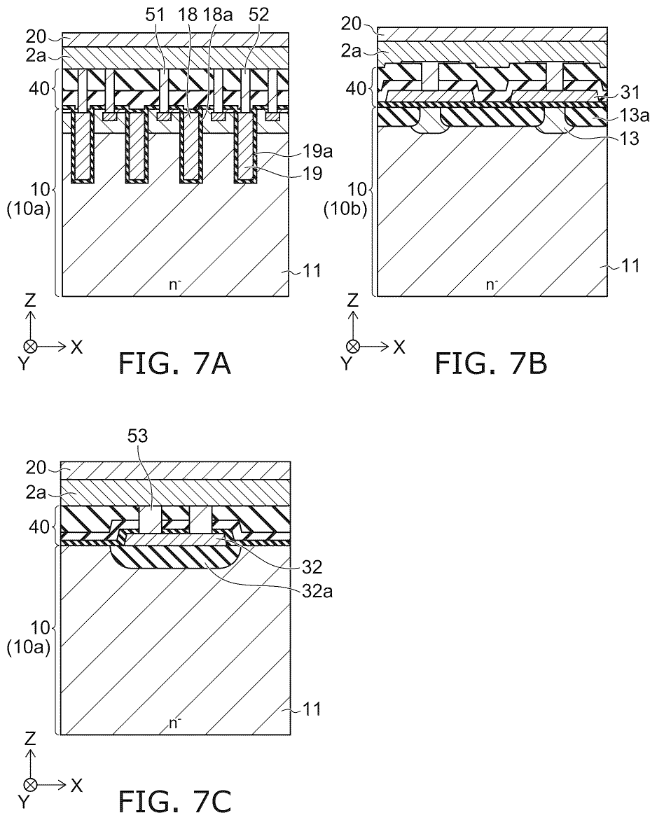

A first metal layer 2a is formed on the insulating layer 40 by sputtering. The first metal layer 2a includes aluminum. As shown in FIGS. 7A to 7C, a layer 20 is formed on the first metal layer 2a. When the layer 20 includes silicon nitride, the layer 20 can be formed by CVD.

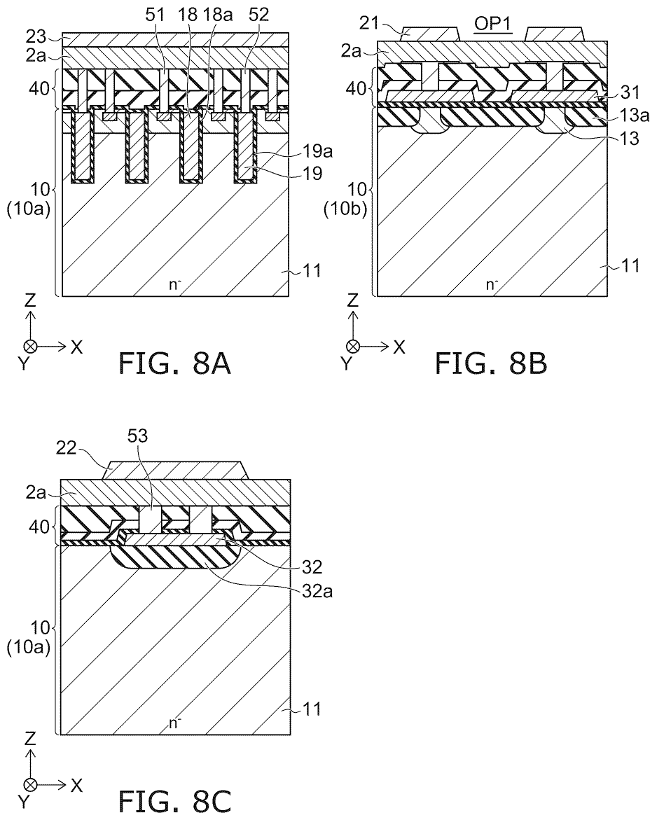

A portion of the layer 20 is removed by photolithography and reactive ion etching (RIE). As a result, as shown in FIGS. 8A to 8C, the layer 20 is divided into multiple parts, and multiple first layers 21, a second layer 22, and a third layer 23 are formed. Each of the multiple first layers 21 is positioned on a respective one of the multiple p⁺-type guard ring regions 13 and on a respective one of the multiple first conductive layers 31. The multiple first layers 21 are separated from each other in the first direction. An opening OP1 is formed between the first layers 21. The second layer 22 is positioned on the second conductive layer 32. The third layer 23 is positioned on the p-type semiconductor region 12, the n⁺-type semiconductor region 14, the gate electrode 18, the field plate electrode 19, etc.

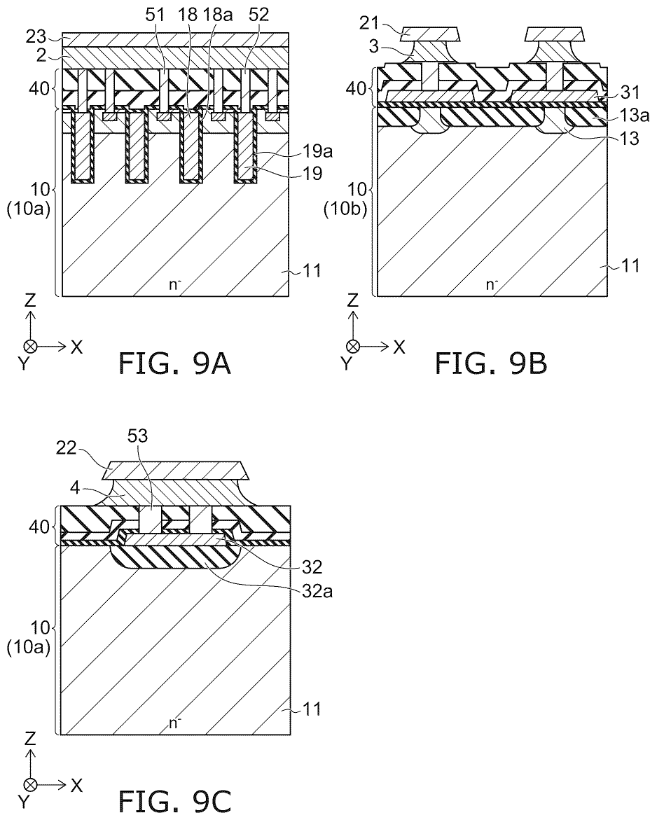

A portion of the first metal layer 2a is etched using the multiple first layers 21, the second layer 22, and the third layer 23 as a mask. This etching includes wet etching of that portion of the first metal layer 2a. As a result of the etching, as shown in FIGS. 9A to 9C, the first metal layer 2a is divided into multiple parts, and the upper electrode 2, multiple GR electrodes 3, and the gate pad 4 are formed. Additionally, a peripheral electrode 5 (not shown) is formed. Each of the multiple GR electrodes 3 is positioned on a respective one of the multiple p⁺-type guard ring regions 13 and on a respective one of the multiple first conductive layers 31. The multiple GR electrodes 3 are separated from each other in the first direction.

During wet etching, the first metal layer 2a is selectively removed with respect to the first layers 21, the second layer 22, and the third layer 23. As long as the first metal layer 2a including aluminum can be selectively removed, the materials for the first layers 21, the second layer 22, and the third layer 23 may be appropriately selected. For example, the first layers 21, the second layer 22, and the third layer 23 include one or more selected from the first group consisting of silicon, gold, tungsten, titanium, copper, and tin. As the chemical solution used for wet etching, CMK (registered trademark), phosphoric acid, nitric acid, or hydrofluoric acid can be used. These chemical solutions have a high etching rate for aluminum, making the first metal layer 2a easy to selectively etch. For example, when the first layers 21, the second layer 22, and the third layer 23 include silicon nitride, at least one chemical solution selected from the group consisting of CMK (registered trademark), hydrofluoric acid, and nitric acid can be used.

During wet etching, the first metal layer 2a is isotropically removed. Therefore, after etching, the width of the upper part of the GR electrode 3 becomes narrower than the width of the lower part of the GR electrode 3 and the width of the first layer 21. The width of the upper part of the gate pad 4 becomes narrower than the width of the lower part of the gate pad 4 and the width of the second layer 22.

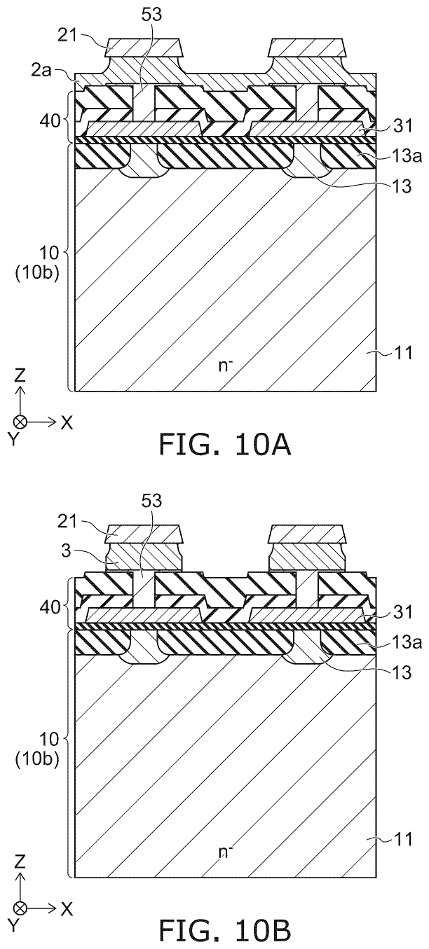

The etching may include the wet etching shown in FIG. 10A and the RIE shown in FIG. 10B. As shown in FIG. 10A, a portion of the first metal layer 2a is isotropically etched by wet etching. As shown in FIG. 10B, a portion of the first metal layer 2a is anisotropically etched by RIE. By RIE, the first metal layer 2a is divided into multiple parts, and the upper electrode 2, multiple GR electrodes 3, and the gate pad 4 are formed. In this case as well, after etching, the width of the upper part of the GR electrode 3 becomes narrower than the width of the lower part of the GR electrode 3 and the width of the first layer 21. Also, although not shown in FIG. 10B, the width of the upper part of the gate pad 4 becomes narrower than the width of the lower part of the gate pad 4 and the width of the second layer 22.

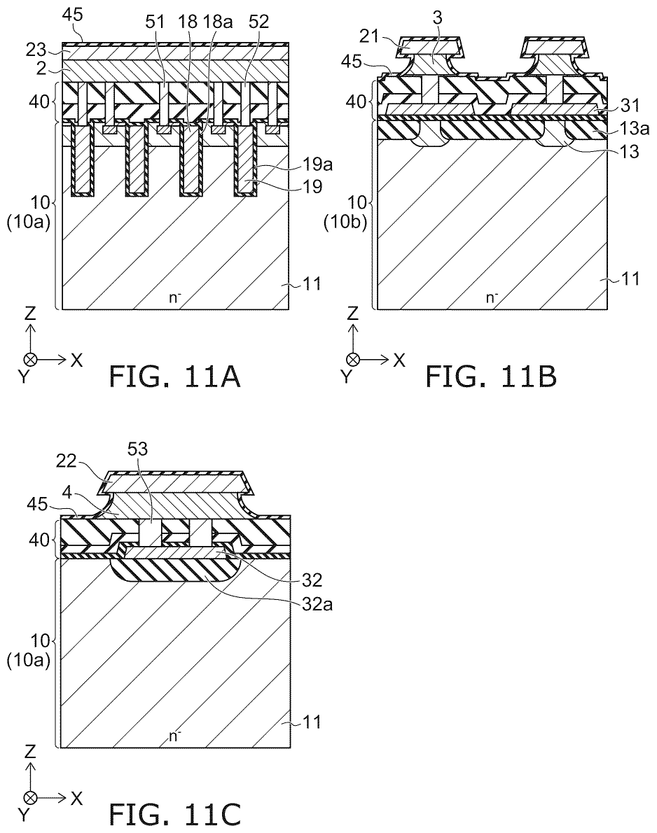

As shown in FIGS. 11A to 11C, the insulating layer 45 is formed by CVD on the side surfaces of each GR electrode 3, on the side surface of the gate pad 4, on the surface of the first layer 21, on the surface of the second layer 22, and on the surface of the third layer 23.

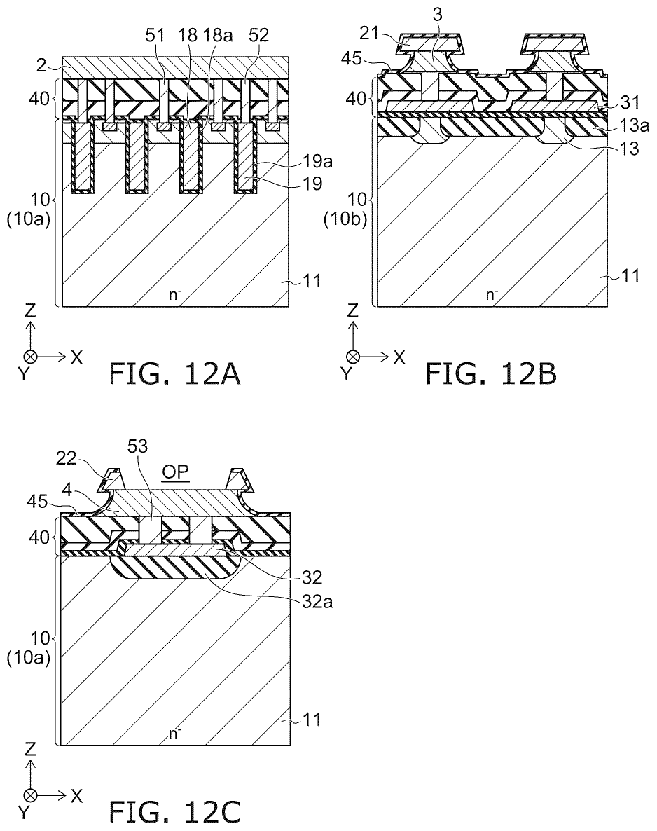

Photolithography and RIE are performed. As a result, as shown in FIG. 12A, the third layer 23 and the insulating layer 45 that had been formed on the upper electrode 2 are removed, and the surface of the upper electrode 2 is exposed. As shown in FIG. 12C, the opening OP is formed in the second layer 22 and the insulating layer 45 on the gate pad 4. During this process, as shown in FIG. 12B, the GR electrode 3 and the first layer 21 remain unprocessed.

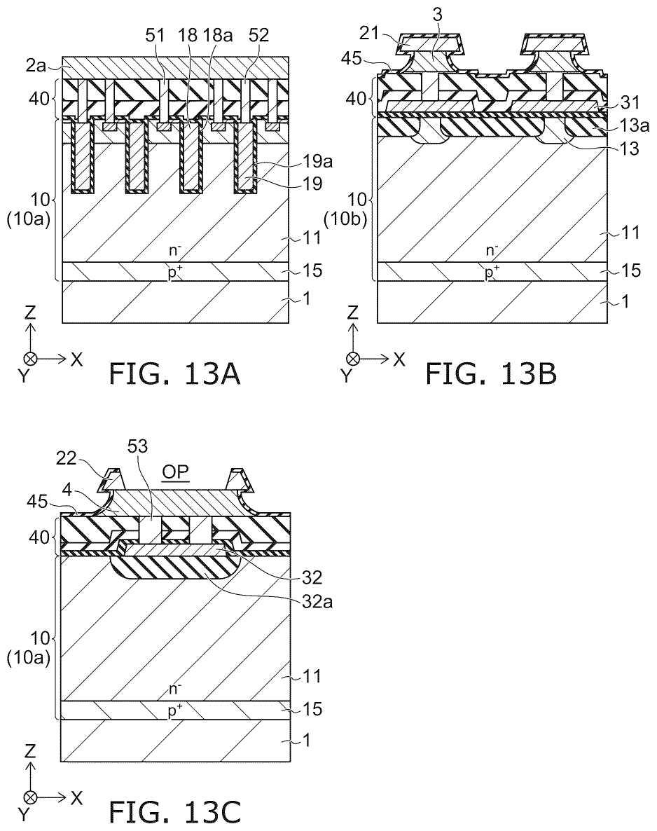

The lower surface of the semiconductor layer 10 is ground until the semiconductor layer 10 reaches a predetermined thickness. p-type impurities are ion-implanted into the ground lower surface to form the p⁺-type collector region 15. As shown in FIGS. 13A to 13C, the lower electrode 1 is formed under the p⁺-type collector region 15 by sputtering. Through the above steps, the semiconductor device 100 according to the first embodiment is manufactured.

Advantages of the semiconductor device according to the first embodiment will be described.

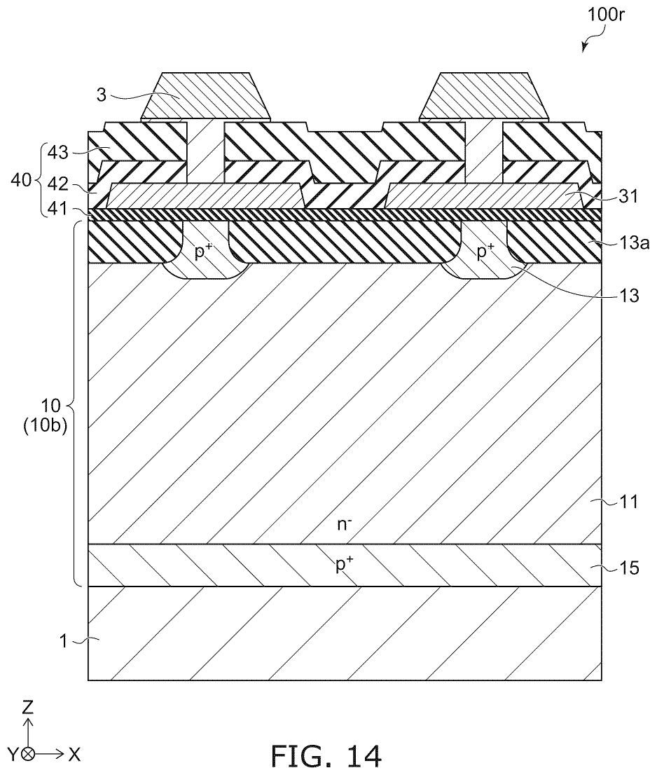

FIG. 14 is a cross-sectional view illustrating a part of a semiconductor device according to a reference example. The semiconductor device 100r shown in FIG. 14 does not include the first layer 21. The width of the upper part of the GR electrode 3 is narrower than the width of the lower part of the GR electrode 3. Between adjacent GR electrodes 3, the distance between the upper parts is greater than the distance between the lower parts.

During the operation of the semiconductor device 100r, an electric field is generated around the semiconductor device 100r. Charges such as ions and electrons move along the electric field above the second portion 10b. When charges reach the interface between the semiconductor layer 10 and the insulating layer 40, the expansion of the depletion layer from the first portion 10a toward the second portion 10b varies due to those charges. Furthermore, the semiconductor device 100r may be covered with an insulating resin. In such case, when charges accumulate in the resin portion between the GR electrodes 3 and charge-up occurs, the expansion of the depletion layer from the first portion 10a toward the second portion 10b varies. When the expansion of the depletion layer varies due to these factors, the withstand voltage of the semiconductor device 100r may decrease.

In the semiconductor device 100r, the distance between the upper parts of the GR electrodes 3 is increased compared with their lower parts. Therefore, charges can more easily enter between the GR electrodes 3. Charges can more easily reach the interface between the semiconductor layer 10 and the insulating layer 40, and as a result, the withstand voltage of the semiconductor device 100r tends to fluctuate. Also, when the semiconductor device 100r is covered with an insulating resin, charges are more likely to accumulate in the resin portion between the GR electrodes 3.

In the semiconductor device 100 according to the first embodiment, the first layer 21 is provided on the GR electrode 3. As shown in FIG. 4, the width W3 of the first layer 21 is wider than the width W1 of the upper part of the GR electrode 3. Since the first layer 21 is electrically connected to GR electrode 3, charges entering the first layer 21 travel within it or move to GR electrode 3. This can suppress the charge moves into the region between the GR electrodes 3. As a result, for example, it becomes more difficult for charges to reach the interface between the semiconductor layer 10 and the insulating layer 40. Also, even when the semiconductor device 100 is covered with an insulating resin, charge-up is less likely to occur at a position close to the semiconductor layer 10. Consequently, the expansion of the depletion layer in the second portion 10b can be more stabilized. According to the first embodiment, the withstand voltage of the semiconductor device can be more stabilized.

Additionally, in the semiconductor device 100, the width W1 of the upper part of the GR electrode 3 is narrower than the width W3 of the first layer 21. Therefore, compared to the case where the width W1 and the width W3 are the same, the electrical resistance between the first layer 21 and the GR electrode 3 can be increased. For example, if a large amount of charge moves to the GR electrode 3 through the first layer 21, the potential of the GR electrode 3 may vary, which could affect the expansion of the depletion layer. By increasing the electrical resistance between the first layer 21 and the GR electrode 3, it becomes more difficult for the charge that has entered the first layer 21 to move to the GR electrode 3. As a result, the expansion of the depletion layer in the second portion 10b can be further stabilized.

Advantages of the manufacturing method according to the first embodiment will be described.

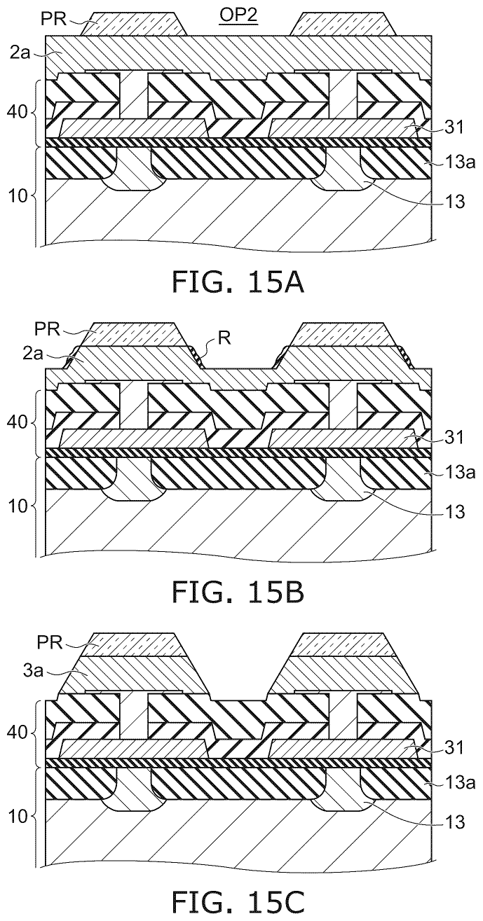

FIGS. 15A to 15C are cross-sectional views illustrating a manufacturing method according to the reference example. In the manufacturing method according to the reference example, multiple photoresist layers PR are formed on the first metal layer 2a as shown in FIG. 15A. An opening OP2 is formed between the photoresist layers PR. A portion of the first metal layer 2a is removed by RIE using the multiple photoresist layers PR as a mask. During RIE, a gas including chlorine is used. When the aluminum included in the first metal layer 2a reacts with chlorine, a reaction product R is formed on the side surfaces of the first metal layer 2a during the RIE, as shown in FIG. 15B.

When the reaction product R is formed and then, in subsequent steps, the reaction product R peels off and moves, a short-circuit between electrodes may occur.

To suppress the formation of the reaction product R, as shown in FIG. 15B, it is preferable to incline the side surfaces of the first metal layer 2a formed by processing at a large angle with respect to the Z-direction. When the side surfaces are greatly inclined, the reaction product R formed on the side surfaces is removed during the RIE by ions advancing in the Z-direction. As a result, as shown in FIG. 15C, a GR electrode 3a with greatly inclined side surfaces is formed.

According to the manufacturing method of the reference example, the deposition of the reaction product R can be suppressed. On the other hand, as the inclination of the side surfaces of the GR electrode 3a increases, the distance between the upper parts of the GR electrodes 3a also increases. For example, charges can more easily enter between the GR electrodes 3a, and as a result, the withstand voltage of the semiconductor device 100r tends to fluctuate.

According to the manufacturing method of the first embodiment, a portion of the first metal layer 2a is removed by wet etching. The chemical solution used for wet etching includes substantially no chlorine. By using wet etching, the formation of the reaction product can be suppressed. On the other hand, when wet etching is used, the first metal layer 2a is isotropically removed. Therefore, similar to FIGS. 15B and 15C, the side surfaces of the GR electrode 3 after etching may be greatly inclined with respect to the Z-direction. To address this issue, in the first embodiment, the first layer 21 provided on the first metal layer 2a is used as a mask for wet etching. The first metal layer 2a is selectively etched with respect to the first layer 21. Therefore, after wet etching, the width of the first layer 21 is wider than the width of the GR electrode 3 formed by etching. The first layer 21 is electrically connected to the GR electrode 3, and charges can move within the first layer 21. By providing the first layer 21, movement of charges between GR electrodes 3 can be suppressed. For example, the movement of charges to the interface between the semiconductor layer 10 and the insulating layer 40 can be suppressed. In addition, the generation of charge-up in the region between the GR electrodes 3 can be suppressed.

According to the first embodiment, the formation of the reaction product R on the side surfaces of the GR electrode 3 and the short-circuit between electrodes can be suppressed, thereby improving the reliability of the semiconductor device 100. Additionally, according to the first embodiment, since a first layer 21 having a wider width can be formed on the GR electrode 3, the decrease in the withstand voltage of the semiconductor device 100 due to external charges can also be suppressed.

### Modification

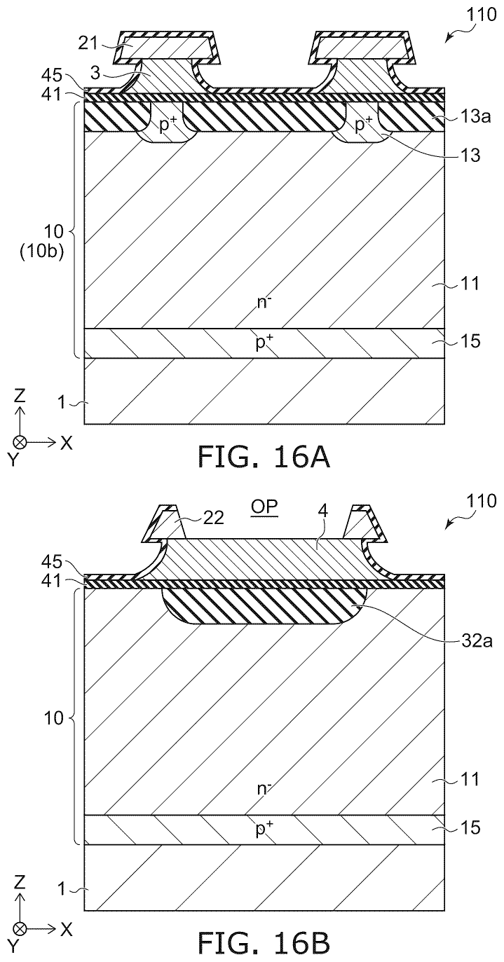

FIGS. 16A and 16B are cross-sectional views illustrating a part of a semiconductor device according to a modification of the first embodiment.

Compared to the semiconductor device 100, in the semiconductor device 110, the first conductive layer 31 and the contact plug 53 are omitted, as shown in FIG. 16A. In the semiconductor device 110, the GR electrode 3 faces the p⁺-type guard ring region 13 via the insulating layer 41. Second conductive layer 32 and contact plug 54 may likewise be omitted, as shown in FIG. 16B. The gate pad 4 faces the insulating portion 32a via the insulating layer 41.

As shown in FIGS. 16A and 16B, in the semiconductor device according to the first embodiment, specific configurations other than the GR electrode 3, the gate pad 4, the first layer 21, and the second layer 22 may be appropriately modified.

### Second Embodiment

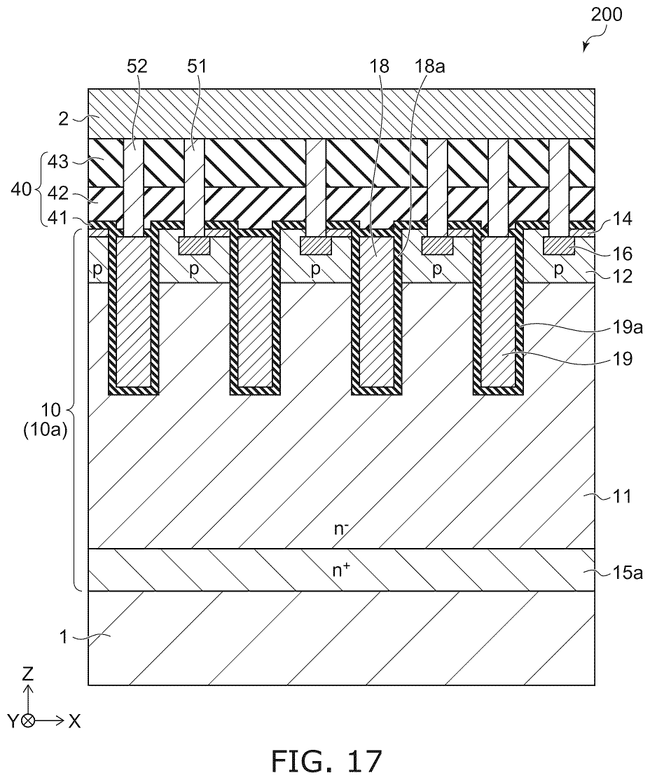

FIG. 17 is a cross-sectional view illustrating a part of a semiconductor device according to a second embodiment.

The semiconductor device 200 is a Metal Oxide Semiconductor Field Effect Transistor (MOSFET). In the semiconductor device 200, the semiconductor layer 10 includes an n⁺-type semiconductor region 15a instead of the p⁺-type collector region 15, as shown in FIG. 17. The n⁺-type semiconductor region 15a is located between the lower electrode 1 and the n⁻-type semiconductor region 11. The n-type impurity concentration in the n⁺-type semiconductor region 15a is greater than the n-type impurity concentration in the n⁻-type semiconductor region 11.

Other components of the semiconductor device 200 may be the same as those of the semiconductor device 100. For example, the GR electrode 3 and the first layer 21 are provided on the second portion 10b, as in the example shown in FIG. 4. The width of the upper part of the GR electrode 3 is narrower than the width of the lower part of the GR electrode 3, and the width of the first layer 21 is wider than the width of the upper part of the GR electrode 3.

In the semiconductor device 200, the lower electrode 1 functions as a drain electrode. The upper electrode 2 functions as a source electrode. When a positive voltage is applied to the lower electrode 1 relative to the upper electrode 2, a voltage exceeding the threshold is applied to the gate electrode 18. As a result, a channel is formed in the p-type semiconductor region 12. Electrons flow through the channel from the n⁺-type semiconductor region 14 to the n⁻-type semiconductor region 11; and the semiconductor device 200 is turned on. Thereafter, when the voltage applied to the gate electrode 18 falls below the threshold, the channel in the p-type semiconductor region 12 disappears; and the semiconductor device 200 switches to an off-state.

When the semiconductor device 200 switches to an off-state, a depletion layer expands from the first portion 10a toward the second portion 10b as in the semiconductor device 100. According to the second embodiment, by providing the GR electrode 3 and the first layer 21 above the second portion 10b, the expansion of the depletion layer in the second portion 10b can be more stabilized, and the variation in the withstand voltage of the semiconductor device 200 can be suppressed.

### Third Embodiment

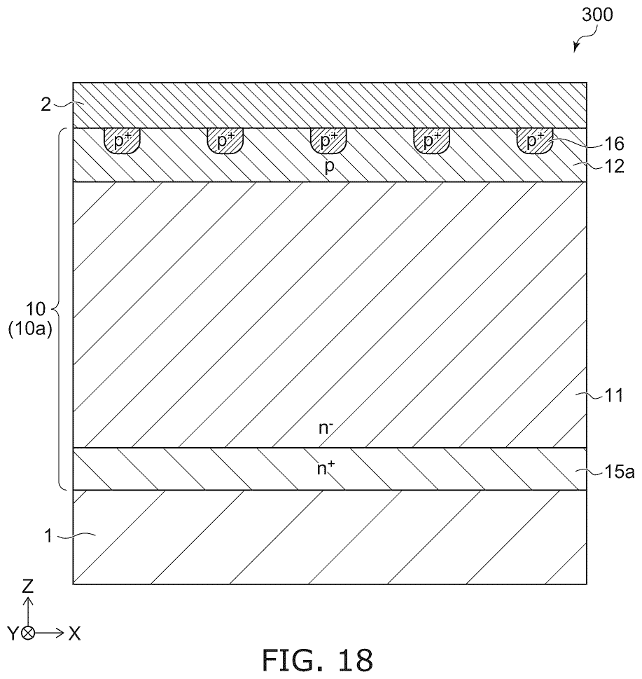

FIG. 18 is a cross-sectional view illustrating a part of a semiconductor device according to a third embodiment.

The semiconductor device 300 is a diode. In the semiconductor device 300, the semiconductor layer 10 does not include the n⁺-type semiconductor region 14 or the gate electrode 18, which makes it different from the semiconductor device 200. In the illustrated example, furthermore, the field plate electrode 19, the contact plug 51, the contact plug 52, the insulating layer 40, etc. are omitted.

Other components of the semiconductor device 300 may be the same as those of the semiconductor device 100. For example, the GR electrode 3 and the first layer 21 are provided on the second portion 10b as in the example shown in FIG. 4. The width of the upper part of the GR electrode 3 is narrower than the width of the lower part of the GR electrode 3, and the width of the first layer 21 is wider than the width of the upper part of the GR electrode 3.

In the semiconductor device 300, the lower electrode 1 functions as a cathode electrode. The upper electrode 2 functions as an anode electrode. When a positive voltage is applied to the upper electrode 2 relative to the lower electrode 1, a forward voltage is applied to the p-n junction between the n⁻-type semiconductor region 11 and the p-type semiconductor region 12, and current flows from the upper electrode 2 to the lower electrode 1.

When the semiconductor device 300 switches to an off-state, as in the semiconductor device 100, a depletion layer expands from the first portion 10a toward the second portion 10b. According to the third embodiment, by providing the GR electrode 3 and the first layer 21 above the second portion 10b, the expansion of the depletion layer in the second portion 10b can be more stabilized, and the variation in the withstand voltage of the semiconductor device 300 can be suppressed.

The embodiment includes the following features.

### Feature 1

A semiconductor device, comprising:
a first electrode;
a semiconductor layer provided on the first electrode, the semiconductor layer including
   a first portion, and
   a second portion provided around the first portion along a first plane, the first plane being perpendicular to a direction from the first electrode toward the semiconductor layer;
a second electrode provided on the first portion;
a third electrode provided on the second portion via an insulating layer, the third electrode being located around the second electrode along the first plane, a length of an upper part of the third electrode in a first direction being shorter than a length of a lower part of the third electrode in the first direction, the first direction being from the first portion toward the second portion; and
a first layer provided on the third electrode and electrically connected to the third electrode, a length of the first layer in the first direction being greater than the length of the upper part.

### Feature 2

A semiconductor device, comprising:
a first electrode;
a semiconductor layer provided on the first electrode, the semiconductor layer including
   a first portion, and
   a second portion provided around the first portion along a first plane, the first plane being perpendicular to a direction from the first electrode toward the semiconductor layer;
a second electrode provided on the first portion;
a third electrode provided on the second portion via an insulating layer, the third electrode being located around the second electrode along the first plane; and
a first layer provided on the third electrode and electrically connected to the third electrode, a length of the first layer in a first direction being greater than the length of the upper part of the third electrode in the first direction, the first direction being from the first portion toward the second portion, the first layer is not in direct contact with a lower part of the third electrode.

### Feature 3

The semiconductor device according to feature 1 or 2, wherein
the semiconductor layer includes
   a first semiconductor region of a first conductivity type provided in the first portion and the second portion,
   a second semiconductor region of a second conductivity type provided on the first semiconductor region and located in the first portion, and
   a third semiconductor region of the second conductivity type provided on the first semiconductor region, the third semiconductor region being located in the second portion and positioned around the second semiconductor region along the first plane, and
the third electrode is positioned above the third semiconductor region.

### Feature 4

The semiconductor device according to feature 3, wherein
a plurality of the third semiconductor regions, a plurality of the third electrodes, and a plurality of the first layers are provided in the first direction,
the plurality of third electrodes are respectively positioned above the plurality of third semiconductor regions via the insulating layer, and
the plurality of first layers are respectively positioned on the plurality of third electrodes.

### Feature 5

The semiconductor device according to feature 3, wherein
the semiconductor layer further includes
   a fourth semiconductor region of the first conductivity type provided on the second semiconductor region, and
   a gate electrode facing the second semiconductor region via a gate insulating layer.

### Feature 6

The semiconductor device according to feature 5, wherein
the semiconductor layer further includes a fifth semiconductor region of the second conductivity type, and
the fifth semiconductor region is provided between the first electrode and the first portion.

### Feature 7

The semiconductor device according to any one of features 1 to 6, wherein
the first layer includes silicon nitride, and
an electrical resistivity of the first layer is less than 1.0×10¹³ Ω·cm.

### Feature 8

The semiconductor device according to feature 2, wherein
a length of an upper part of the third electrode in the first direction being shorter than a length of a lower part of the third electrode in the first direction.

### Feature 9

A method for manufacturing a semiconductor device, comprising:
preparing a structure that includes
   a semiconductor layer including a first portion and a second portion provided around the first portion along a first plane, and
   a first metal layer provided on the first portion and the second portion of the semiconductor layer, the first metal layer including aluminum, a direction from the semiconductor layer toward the first metal layer being perpendicular to the first plane;
forming a plurality of first layers on the first metal layer, the plurality of first layers located above the second portion and separated from each other in a first direction that is from the first portion toward the second portion;
etching a portion of the first metal layer using the plurality of first layers as a mask to form a plurality of electrodes, the plurality of electrodes being separated from each other in the first direction, the etching including wet etching on the portion of the first metal layer.

### Feature 10

The method according to feature 9, wherein
the etching further includes reactive ion etching of the portion of the first metal layer after the wet etching.

### Feature 11

The method according to feature 9, wherein
after the etching, a length of an upper part of one of the plurality of electrodes in the first direction is shorter than a length of a lower part of the one of the plurality of electrodes in the first direction and shorter than a length of one of the plurality of first layers.

### Feature 12

The method according to any one of features 9 to 11, wherein
at least one of the plurality of first layers include silicon nitride, and
an electrical resistivity of the at least one of the plurality of first layers is less than 1.0×10¹³ Ω·cm.

According to the embodiments described above, a semiconductor device and its manufacturing method capable of stabilizing the withstand voltage more are provided.

In the embodiments above, the relative levels of the impurity concentrations between the semiconductor regions can be confirmed using, for example, a scanning capacitance microscope (SCM). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured, for example, using secondary ion mass spectrometry (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a first electrode;
a semiconductor layer provided on the first electrode, the semiconductor layer including
a first portion, and
a second portion provided around the first portion along a first plane, the first plane being perpendicular to a direction from the first electrode toward the semiconductor layer;
a second electrode provided on the first portion;
a third electrode provided on the second portion via an insulating layer, the third electrode being located around the second electrode along the first plane, a length of an upper part of the third electrode in a first direction being shorter than a length of a lower part of the third electrode in the first direction, the first direction being from the first portion toward the second portion; and
a first layer provided on the third electrode and electrically connected to the third electrode, a length of the first layer in the first direction being greater than the length of the upper part.

2. The semiconductor device according to claim 1, wherein
the semiconductor layer includes
a first semiconductor region of a first conductivity type provided in the first portion and the second portion,
a second semiconductor region of a second conductivity type provided on the first semiconductor region and located in the first portion, and
a third semiconductor region of the second conductivity type provided on the first semiconductor region, the third semiconductor region being located in the second portion and positioned around the second semiconductor region along the first plane, and
the third electrode is positioned above the third semiconductor region.

3. The semiconductor device according to claim 2, wherein
a plurality of the third semiconductor regions, a plurality of the third electrodes, and a plurality of the first layers are provided in the first direction,
the plurality of third electrodes are respectively positioned above the plurality of third semiconductor regions via the insulating layer, and
the plurality of first layers are respectively positioned on the plurality of third electrodes.

4. The semiconductor device according to claim 2, wherein
the semiconductor layer further includes
a fourth semiconductor region of the first conductivity type provided on the second semiconductor region, and
a gate electrode facing the second semiconductor region via a gate insulating layer.

5. The semiconductor device according to claim 4, wherein
the semiconductor layer further includes a fifth semiconductor region of the second conductivity type, and
the fifth semiconductor region is provided between the first electrode and the first portion.

6. The semiconductor device according to claim 1, wherein
the first layer includes silicon nitride, and
an electrical resistivity of the first layer is less than 1.0×10¹³ Ω·cm.

7. A semiconductor device, comprising:
a first electrode;
a semiconductor layer provided on the first electrode, the semiconductor layer including
a first portion, and
a second portion provided around the first portion along a first plane, the first plane being perpendicular to a direction from the first electrode toward the semiconductor layer;
a second electrode provided on the first portion;
a third electrode provided on the second portion via an insulating layer, the third electrode being located around the second electrode along the first plane; and
a first layer provided on the third electrode and electrically connected to the third electrode, a length of the first layer in a first direction being greater than a length of an upper part of the third electrode in the first direction, the first direction being from the first portion toward the second portion, the first layer is not in direct contact with a lower part of the third electrode.

8. The semiconductor device according to claim 7, wherein
the semiconductor layer includes
a first semiconductor region of a first conductivity type provided in the first portion and the second portion,
a second semiconductor region of a second conductivity type provided on the first semiconductor region and located in the first portion, and
a third semiconductor region of the second conductivity type provided on the first semiconductor region, the third semiconductor region being located in the second portion and positioned around the second semiconductor region along the first plane, and
the third electrode is positioned above the third semiconductor region.

9. The semiconductor device according to claim 8, wherein
a plurality of the third semiconductor regions, a plurality of the third electrodes, and a plurality of the first layers are provided in the first direction,
the plurality of third electrodes are respectively positioned above the plurality of third semiconductor regions via the insulating layer, and
the plurality of first layers are respectively positioned on the plurality of third electrodes.

10. The semiconductor device according to claim 8, wherein
the semiconductor layer further includes
a fourth semiconductor region of the first conductivity type provided on the second semiconductor region, and
a gate electrode facing the second semiconductor region via a gate insulating layer.

11. The semiconductor device according to claim 10, wherein
the semiconductor layer further includes a fifth semiconductor region of the second conductivity type, and
the fifth semiconductor region is provided between the first electrode and the first portion.

12. The semiconductor device according to claim 7, wherein
the first layer includes silicon nitride, and
an electrical resistivity of the first layer is less than 1.0×10¹³ Ω·cm.

13. The semiconductor device according to claim 7, wherein
a length of an upper part of the third electrode in the first direction being shorter than a length of a lower part of the third electrode in the first direction.

14. A method for manufacturing a semiconductor device, comprising:
preparing a structure that includes
a semiconductor layer including a first portion and a second portion provided around the first portion along a first plane, and
a first metal layer provided on the first portion and the second portion of the semiconductor layer, the first metal layer including aluminum, a direction from the semiconductor layer toward the first metal layer being perpendicular to the first plane;
forming a plurality of first layers on the first metal layer, the plurality of first layers located above the second portion and separated from each other in a first direction that is from the first portion toward the second portion;
etching a portion of the first metal layer using the plurality of first layers as a mask to form a plurality of electrodes, the plurality of electrodes being separated from each other in the first direction, the etching including wet etching on the portion of the first metal layer.

15. The method according to claim 14, wherein
the etching further includes reactive ion etching of the portion of the first metal layer after the wet etching.

16. The method according to claim 14, wherein
after the etching, a length of an upper part of one of the plurality of electrodes in the first direction is shorter than a length of a lower part of the one of the plurality of electrodes in the first direction and shorter than a length of one of the plurality of first layers.

17. The method according to claim 14, wherein
at least one of the plurality of first layers include silicon nitride, and
an electrical resistivity of the at least one of the plurality of first layers is less than 1.0×10¹³ Ω·cm.
